(19) United States
(12) Patent Application Publication
(10) Pub. No.: US 2009/0153882 A1
(43) Pub. Date: Jun. 18, 2009

(54) Measuring Dimensional Parameters of Structures

(76) Inventors: Thomas Geiler, Ludwigsburg (DE); Manfred Moert, Dresden (DE)

Correspondence Address: SLATER & MATSIL, L.L.P., 17950 PRESTON ROAD, SUITE 1000, DALLAS, TX, 75252, US

(21) Appl. No.: 11/957,214

(22) Filed: Dec. 14, 2007

(51) Int. Cl. G01J 5/02; H01L 31/02

(52) U.S. Cl. 356/625; 250/340; 257/53; 257/E31.002

(57) ABSTRACT

Dimensional parameters of structures on a substrate are measured by providing a substrate with a structured surface. The structured surface includes a number of juxtaposed structural elements. A radiation source is configured to emit a beam of radiation having a wavelength in the infrared range. The substrate is illuminated with the beam of radiation. A signal corresponding to a part of the beam of radiation being transmitted through the substrate is detected. Dimensional parameters of the structural elements are calculated based on the transmitted beam signal.

### TECHNICAL FIELD

Embodiments of the invention relate to scatterometry for measuring structural dimensions and methods for measuring structures of an integrated circuit and further relate to fabrication units for manufacturing an integrated circuit.

### BRIEF DESCRIPTION OF THE DRAWINGS

In the accompanying drawings:

FIG. 1 illustrates an optical projection system;

FIG. 2A illustrates a layout pattern in a cross-sectional side view according to an embodiment;

FIG. 2B illustrates a layout pattern in a top view according to an embodiment;

FIG. 3 illustrates spectral sensitivity for different structure depths for different configurations at a given pitch value of 1 μm according to an embodiment;

FIG. 4 illustrates spectral sensitivity for different structure depths for different configurations at a given pitch value of 0.22 μm according to an embodiment;

FIG. 5 illustrates spectral sensitivity for different structure depths for different configurations at a given pitch value of 10 μm according to an embodiment;

FIG. 6 illustrates a flow chart of method steps for performing measurement of structural dimensions according to an embodiment; and

FIG. 7 illustrates a fabrication unit for manufacturing an integrated circuit according to an embodiment.

### DETAILED DESCRIPTION OF ILLUSTRATIVE EMBODIMENTS

Embodiments of methods and systems of determining structural features by scatterometry are discussed in detail below. It is appreciated, however, that the present invention provides many applicable inventive concepts that can be embodied in a wide variety of specific contexts. The specific embodiments discussed are merely illustrative of specific ways and do not limit the scope of the invention.

In the following, embodiments of the method and the system are described with respect to determining structural features by scatterometry during manufacturing of an integrated circuit. The embodiments, however, might also be useful in other respects, e.g., improvements in process control, improvements in identifying lot to lot variations of a layout pattern, yield enhancement techniques or the like.

Furthermore, it should be noted that the embodiments are described with respect to line-space-patterns but might also be useful in other respects including but not limited to dense patterns, semi dense patterns, patterns with isolated lines or contact hole patterns and combinations between all of them. Lithographic projection can also be applied during manufacturing of different products, e.g., semiconductor circuits, thin film elements. Other products, e.g., liquid crystal panels, micromechanical systems or the like might be produced as well.

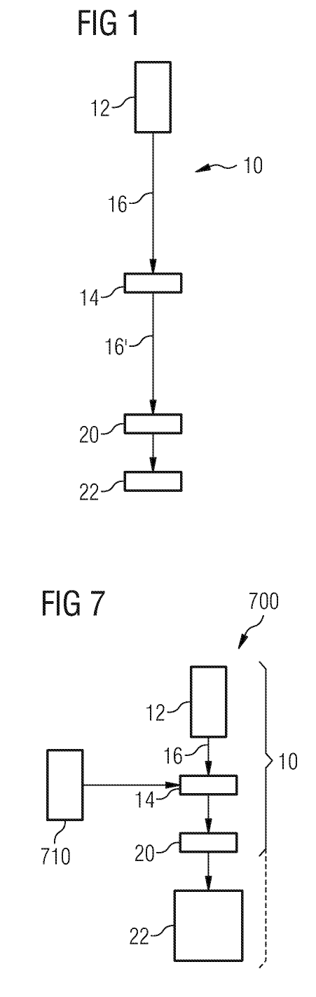

FIG. 1 illustrates basic elements of a scatterometer 10 shown in a side view. It should be noted, however, that FIG. 1 serves merely illustrative purposes and therefore does not provide full functionality of a scatterometer system. Those skilled in the art will appreciate that there are many variations possible.

According to an embodiment of the invention the scatterometer 10 includes a radiation source 12 which is configured to emit a beam of radiation onto a substrate 14. The light source can be a lamp emitting radiation having a broad band spectrum with wavelengths in the infrared range. The term “infrared range” includes wavelength starting next to the visible spectrum up to the far infrared spectrum, i.e., up to approximately 25 μm.

Furthermore, it is also conceivable to use a laser as radiation source 12 so as to provide a mono- or poly-chromatic beam. In this case, a further parameter is varied in order to achieve an analyzable spectrum. A suitable further parameter would be the angle of incidence, for example.

The emitted beam 16 is focused on the substrate 14. In order to perform measurements of structures onto sample 14 the spot size of beam 16 should be larger than the structural dimensions of the structures on probe 14. On the other hand it is also possible that the spot size of beam 16 is small enough so as to illuminate only a part of substrate 14, which is arranged in a repetitive pattern.

As shown in FIG. 1, beam 16 is at least partially transmitted through substrate 14. The transmitted beam 16′ is collected and directed to a detector 20 which generates signals corresponding to the measured intensity, for example. In scatterometry, typically several measurements are performed so as to generate output signals as a function of angle of incidence of beam 16 or of the wavelength of the emitted beam 16.

The output signals of detector 20 are transmitted to a processor 22 which calculates profile parameters by evaluating the signals. Furthermore, an interface (not shown in FIG. 1) can be provided which is suitable for sending data from the detector 20 to the processor 22. In this case, processor 22 is not part of the scatterometer 10 or is arranged outside scatterometer 10.

In order to evaluate the signals, it is possible to compare actual measurements to theoretical calculations that usually include a theoretical model of the structure under investigation. In order to describe different structures, model parameters are introduced which relate to a geometrical representation of the probe including, for example, height, width, sidewall angles or the like. Furthermore, material properties such as refraction indices or extinction coefficients are provided. By using Maxwell's equations, for example, it is possible to calculate optical responses of a probe for different parameters.

Accordingly, it is possible to calculate a set of optical responses which are stored as a library of possible responses (for example, in a suitable memory) and can be compared to actual measurements, so as to arrive at a result for the parameter or parameters for a specific sample. In addition, interpolation between different possible responses can be performed, in order to increase accuracy of the result for the parameter or parameters for a specific sample. It should be noted, however, that many other possible approaches can be used in order to arrive at a sample parameter. For example, the theoretical model can be iterated on processor 22 in response to a measurement or a recursion procedure can be applied.

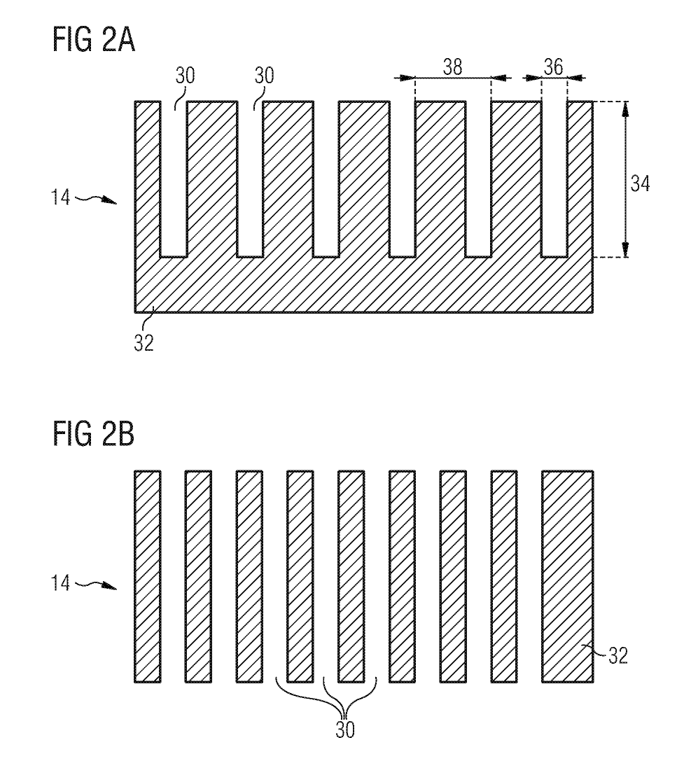

In FIG. 2A, a cross-section through substrate 14 is shown. Substrate 14 includes a structured surface, here shown as a line space grating at a certain periodicity. The line space grating includes trenches 30, which are embedded in a substrate 32. The trenches 30 are arranged symmetrically next to each other. Trenches 30 can have a depth 34 in the range between about 1 to about 10 μm, can have a width 36 of approximately 1 μm and can have a pitch 38 between about 1 and about 20 μm.

It should be noted that FIG. 2A provides a simplified example. It is however also conceivable that a true three dimensional pattern is provided, e.g., a contact hole pattern. Furthermore, the trenches 30 can be covered with additional layers, which are arranged conformal or partial on the structured surface. Additional features of the line space grating can include line edge roughness, line width roughness or sidewall roughness, which are not depicted in the idealized embodiment of FIG. 2A.

In FIG. 2B, the structure of FIG. 2A is shown in a top view. According to FIG. 2B, trenches 30 are juxtaposed next to each other in a regular fashion. It should be noted that in order to arrive at a measurable signal, the beam spot of incident beam 16 covers several trenches 30. As shown on the right-hand side of FIG. 2B the regular trench pattern is no longer present. In order to perform a scatterometry measurement it is usually convenient to restrict the beam within a region covering the regular trench pattern, although this is not necessary as long as the signal is only marginally disturbed or influences of surrounding structures can be attributed for during the analysis of the signal.

It should be noted that the structure shown in FIGS. 2A and 2B only serve for illustration. In general, all periodic structures can be used. “Periodic” means that one or two lateral dimensions are periodically repeated on the surface of probe 14. Accordingly, a contact hole pattern, which has a regular arranged two-dimensional field of contact holes, can also be analysed.

Structures as shown in FIGS. 2A and 2B can be produced using a lithographic projection apparatus having an Excimer laser as a light source. Light coming from the light source is projected through a photo mask, which comprises a mask pattern, i.e., being composed of light absorptive or light attenuating elements. Light absorptive elements can be provided by, e.g., chrome elements. Light attenuating elements can be provided by, e.g., molybdenum-silicate elements. The mask pattern is derived from a layout pattern which can be provided by a computer aided design system, in which structural elements of the layout pattern is generated and stored.

The light passing the photo mask, i.e., not being blocked or attenuated by the above mentioned elements, is projected by a projection lens onto the surface of a semiconductor wafer. The pattern projected on the semiconductor wafer is usually de-magnified, i.e., scaled down by a factor of 4 or 5. A photo resist film layer is deposited on the semiconductor wafer. Onto the resist film layer, the mask pattern is projected. After developing the photo resist film layer a three dimensional resist pattern is formed on the surface of the semiconductor wafer by removing those parts of the photo resist film layer which are exposed with an exposure dose above the exposure dose threshold of the resist film layer. Using the three dimensional resist pattern as an etch mask, trenches 30 can be formed. Furthermore, hard mask processes can be employed as well, i.e., without using a pattern resist film layer for structuring.

In order to arrive at a signal from which parameters can be derived it is necessary that the dimensional parameters of the pattern are in the range of the wavelength used for scatterometry. However, most substrates are not transparent over the full range of wavelength which could be employed for a measurement. For example, visible light is hardly transmitted through a substrate comprising silicon.

According to the embodiment of the invention, infrared radiation is used which has a suitable transmission through a substrate. Accordingly, a signal can be derived which in turn may be used for determining parameters of the structure on the surface of probe 14. When using infrared light the spectral range of beam 16 allows it to measure structures having lateral dimensions in the order micrometer. Although the semiconductor industry aims at ever decreasing structural dimensions, structures of that range are currently used in a wide field of integrated circuits.

As an example, micromechanical systems, high voltage integrated circuits or automotive integrated circuits usually comprise elements having structural dimensions in the range of about 1 μm or larger.

According to an embodiment of the invention it is now possible to measure these structures even without employing other technologies like atomic force microscopy or scanning electron microscopy of a wafer broken along the trench axis which are either time-consuming or destroy the sample 14.

As a transmission mode scatterometer can be readily implemented into a fabrication unit of semiconductor manufacturing equipment it is possible to achieve in situ measurements of structures having lateral dimensions in excess of approximately 1 μm.

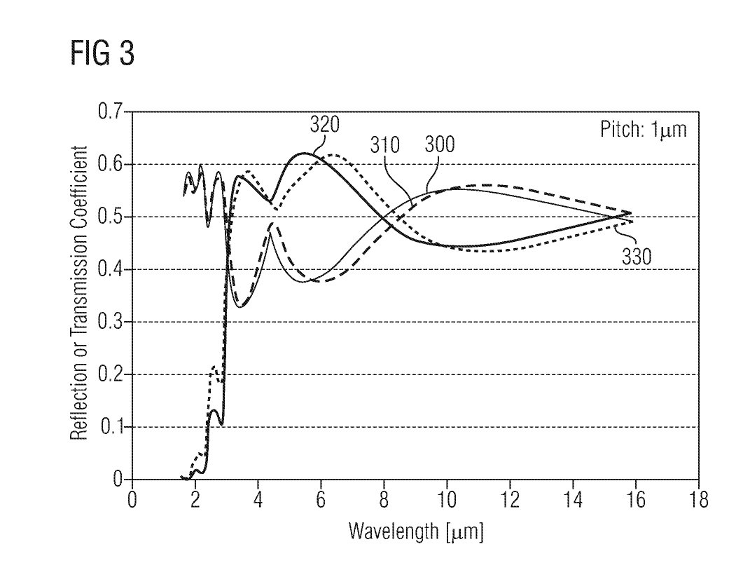

Making reference now to FIGS. 3 to 5, spectral sensitivities are shown for differently sized line space gratings as described with respect to FIGS. 2A and 2B. For comparison, reflection spectra are shown as well.

FIGS. 3 to 5 illustrate spectral sensitivities for transmission coefficients and for reflection coefficients for different structure depths for different configurations at a given pitch value as a function of wavelength of transmitted or reflected radiation. FIGS. 3 to 5 merely illustrate how a variation of a process parameter influences the transmission coefficients and whether the variation of a process parameter results in a detectable signal.

In FIG. 3 a trench pattern having a depth of 1 μm and a pitch of about 1 μm is compared to a pattern having a depth of about 1.1 μm and a pitch of about 1 μm. The incident beam 16 hits the surface of probe 14 at an angle of about 67°. The wavelength is plotted in a range from approximately 1.8 μm up to approximately 16 μm.

In FIG. 3, the spectral sensitivity of transmission coefficients is shown as a function of the wavelength for two different trench depths, resulting in transmission coefficient 300 for a depth of about 1 μm and in transmission coefficient 310 for a depth of about 1.1 μm. As shown in FIG. 3, the transmission coefficients 300 and 310 show pronounced different behavior. Accordingly, the two different structure patterns having a depth of about 1 μm and a depth of about 1.1 μm, respectively, can be separated from each other by measurement.

As a comparison, the spectral sensitivity of reflection coefficients is shown as a function of the wavelength for two different trench depths, as well. Reflection coefficient 320 for a depth of about 1 μm and reflection coefficient 330 for a depth of about 1.1 μm are shown in FIG. 3, which depict similar sensitivity behaviors as compared to the transmission coefficients 300 and 310.

It should be noted, however, that parameter correlations could be different which results in some cases in an increased sensitivity for transmission mode scatterometry.

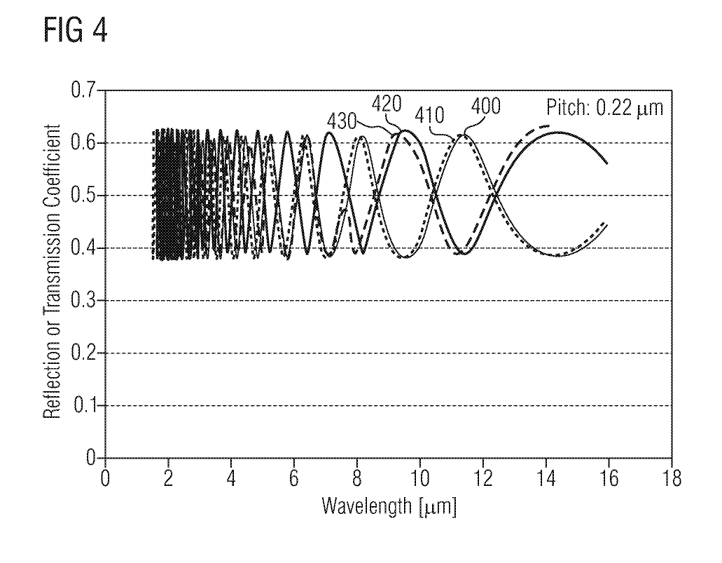

In FIG. 4, the spectral sensitivity of transmission coefficients is shown as a function of the wavelength by employing two different patterns having a pitch of about 0.22 μm and a depth of about 6 μm or about 6.1 μm, respectively. The spectral sensitivity of transmission coefficients is shown as a function of the wavelength for two different trench depths, resulting in transmission coefficient 400 for a depth of about 6 μm and in transmission coefficient 410 for a depth of about 6.1 μm.

Although the behavior of the transmission coefficient 400 and 410 for the two different structures can be separated, the complicated shape of the transmission coefficient makes it rather difficult to analyze the signals. Accordingly, it can be concluded that lateral dimensions of the order of about 0.22 μm resemble a lateral dimension which is at the lower end of the sensitivity range of a transmission mode scatterometer using wavelengths in the infrared range. In other words, the structured surface acts rather like a mixture between the surrounding atmosphere and the material of substrate 14 as substantially no diffraction occurs. For comparison, the spectral sensitivity of reflection coefficients 420 and 430 are shown as a function of the wavelength for two different trench depths, as well.

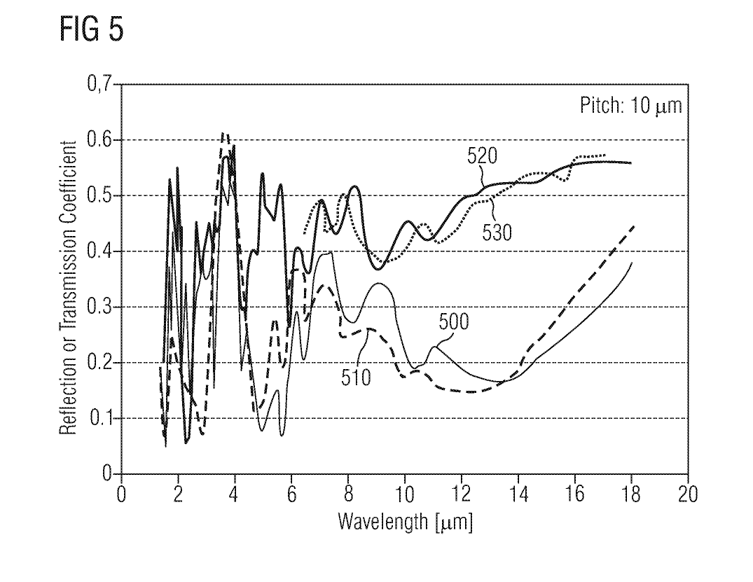

According to FIG. 5 the behavior of the transmission coefficient is investigated for large pitch values. Here the pitch between adjacent trenches is about 10 μm. The depths of the trenches are about 3 or about 2.8 μm, respectively. As it is evident from FIG. 5, the two transmission coefficient curves 500 and 510 show pronounced different behavior which require only a simple theoretical model in order to derive suitable profile parameters as results. As a comparison, the spectral sensitivity of reflection coefficients 520 and 530 shown as a function of the wavelength for two different trench depths as well. By comparing the spectral sensitivities, transmission mode scatterometry in the infrared range appears to be larger than in reflective mode.

When employing transmission mode scatterometry, as shown with respect to FIGS. 3 to 5, it should be noted that part of the transmitted beam 16′ is subjected to reflection on the backside of substrate 14. Effects based on backside reflection can be corrected by employing a filter on the measured spectrum after performing a Fourier transformation. By applying a reverse transformation afterwards, backside reflection effects can be largely reduced.

For the filter, it is conceivable to perform filtering of a certain spectral range, i.e., by employing a band-pass filter, a low-pass filter or the like. Furthermore, a multi band-pass filter can be employed so as to eliminate or reduce excitation spectral lines as well.

It should be noted that it is also conceivable to introduce blades between substrate 14 and detector 20 so as to reduce or eliminate multiple scattered radiation resulting from backside reflection. Another conceivable option is to provide a model which takes into account backside reflection when calculating optical responses of a probe for different parameters.

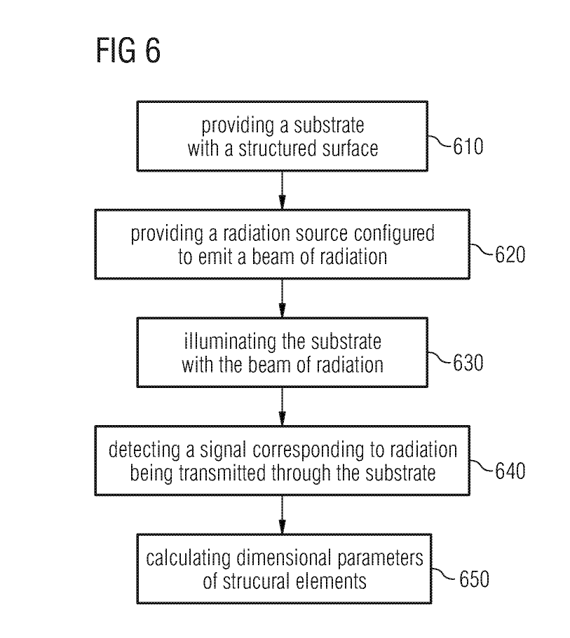

In FIG. 6, a flow diagram is shown with individual process steps capable of measuring dimensional parameters of structures on a substrate.

In step 610 a substrate is provided having a structured surface.

In step 620 a radiation source is provided which is configured to emit a beam of radiation.

In step 630 the substrate is illuminated with the beam of radiation.

In step 640 a signal is detected which corresponds to radiation being transmitted through the substrate.

In step 650 dimensional parameters of structural elements are calculated using a model.

In FIG. 7, a fabrication unit 700 for manufacturing an integrated circuit is shown. The fabrication unit includes a fabrication tool 710 capable of processing the substrate 14 with the structured surface. The structured surface includes a plurality of juxtaposed structural elements, as shown in FIGS. 2A and 2B.

Furthermore, the scatterometry system 10 is provided which includes the radiation source, similar as shown in FIG. 1. Accordingly, the radiation source 12 is configured to emit the beam of radiation 16 having a wavelength in the infrared range. The detector 20 is configured to detect a signal corresponding to a part of the beam of radiation being transmitted through the substrate. The processor 22 for calculating dimensional parameters of the structural elements based on the transmitted beam signal. The fabrication tool is controlled by the calculated dimensional parameters.

Having described embodiments of the invention, it is noted that modifications and variations can be made by persons skilled in the art in light of the above teachings. It is therefore to be understood that changes may be made in the particular embodiments of the invention disclosed which are within the scope and spirit of the invention as defined by the appended claims.

Having thus described the invention with the details and the particularity required by the patent laws, what is claimed and desired to be protected by Letters Patent is set forth in the appended claims. The scope of the invention should, therefore, be determined with reference to the appended claims along with the scope of equivalents to which such claims are entitled.

What is claimed is:

1. A method of measuring dimensional parameters of structures on a substrate, the method comprising:
providing a substrate with a structured surface, the structured surface comprising a plurality of juxtaposed structural elements;
providing a radiation source configured to emit a beam of radiation having a wavelength in the infrared range;
illuminating the substrate with the beam of radiation;
detecting a signal, the signal corresponding to a part of the beam of radiation being transmitted through the substrate; and
calculating dimensional parameters of the structural elements based on a transmitted beam signal.

2. The method according to claim 1, wherein providing the substrate comprises providing the substrate with the structured surface having a trench structure that is arranged symmetrically along a first axis.

3. The method according to claim 1, wherein providing the substrate further comprises providing the substrate with the structured surface having a contact structure that is arranged symmetrically in two dimensions.

4. The method according to claim 1, wherein the transmitted beam signal is subsequently recorded for a plurality of wavelengths of the beam of radiation.

5. A method of measuring dimensional parameters of structures on a substrate, the method comprising:
providing a substrate with a structured surface, the structured surface comprising a plurality of juxtaposed structural elements;
providing a scatterometry system, the scatterometry system having a radiation source configured to emit a beam of radiation having a wavelength in the infrared range and a detector configured to detect a signal corresponding to a part of the beam of radiation being transmitted through the substrate;
transmitting the beam of radiation through the substrate; and
calculating dimensional parameters of the structural elements based on a transmitted beam signal.

6. The method according to claim 5, wherein a processor is used for calculating the dimensional parameters of the structural elements based on the transmitted beam signal.

7. The method according to claim 5, wherein transmitting the beam comprises transmitting the beam through the substrate at a non-right angle relative to a surface of the substrate.

8. The method according to claim 5, wherein transmitting the beam comprises transmitting the beam in a direction perpendicular to a surface of the substrate.

9. The method according to claim 5, wherein the calculating accounts for backside reflection within the substrate.

10. The method according to claim 9, wherein the backside reflection is accounted for by:
performing a Fourier transformation on recorded signals based on the transmitted beam signal;
applying a filter; and
performing a reverse Fourier transformation.

11. The method according to claim 5, further comprising the transmitted beam signal for a plurality of wavelengths of the beam of radiation, the wavelengths ranging between 1 μm and 25 μm.

12. The method according to claim 5, wherein providing the substrate comprises providing the substrate with the structured surface having a trench structure that is symmetrically arranged along a first axis.

13. The method according to claim 5, wherein providing the substrate comprises providing the substrate with the structured surface having a contact structure that is arranged symmetrically in two dimensions.

14. A system of measuring dimensional parameters of structures on a substrate, the system comprising:
a holder for holding a substrate with a structured surface, the structured surface comprising a plurality of juxtaposed structural elements;
a radiation source configured to emit a beam of radiation having a wavelength in the infrared range and capable to illuminate the substrate with the beam of radiation;
a detector for detecting a signal, the signal corresponding to a part of the beam of radiation that is transmitted through the substrate; and
a processor for calculating dimensional parameters of the structural elements based on a transmitted beam signal.

15. The system according to claim 14, wherein the structured surface comprises a trench structure that is arranged symmetrically along a first axis.

16. The system according to claim 14, wherein the structured surface comprises a contact structure that is arranged symmetrically in two dimensions.

17. The system according to claim 14, wherein the processor causes the transmitted beam signal to be subsequently recorded for a plurality of wavelengths of the beam of radiation, the wavelengths ranging between 1 μm and 25 μm.

18. A system of measuring dimensional parameters of structures on a substrate, the system comprising:
means for holding a substrate with a structured surface, the structured surface comprising a plurality of juxtaposed structural elements;
means for emitting a beam of radiation having a wavelength in the infrared range and capable to illuminate the substrate with the beam of radiation;
means for detecting a signal, the signal corresponding to a part of the beam of radiation being transmitted through the substrate; and
means for calculating dimensional parameters of the structural elements based on a transmitted beam signal.

19. A fabrication unit for manufacturing an integrated circuit, the fabrication unit comprising:
a fabrication tool capable of processing a substrate with a structured surface, the structured surface comprising a plurality of juxtaposed structural elements;
a scatterometry system, the scatterometry system having a radiation source configured to emit a beam of radiation having a wavelength in the infrared range and a detector configured to detect a signal corresponding to a part of the beam of radiation being transmitted through the substrate; and
a processor for calculating dimensional parameters of the structural elements based on a transmitted beam signal, wherein the fabrication tool is controlled by the calculated dimensional parameters of the structural elements.
